(19) United States
(12) Patent Application Publication
(10) Pub. No.: US 2024/0231246 A9
(43) Pub. Date: Jul. 11, 2024

(54) APPARATUS FOR TREATING A SUBSTRATE AND METHOD FOR IMPROVING COOLING EFFICIENCY THEREOF

(71) Applicant: SEMES CO., LTD., Cheonan-si (KR)

(72) Inventors: Minhee CHO, Cheonan-si (KR); Hee Man AHN, Cheonan-si (KR); Gyeong Won SONG, Cheonan-si (KR); Jumi LEE, Cheonan-si (KR); Chun Woo PARK, Cheonan-si (KR); Byung Hwi KIM, Cheonan-si (KR)

(73) Assignee: SEMES CO., LTD., Cheonan-si (KR)

(21) Appl. No.: 18/377,300

(22) Filed: Oct. 5, 2023

(30) Foreign Application Priority Data
Oct. 21, 2022 (KR) 10-2022-0136609

(51) Int. Cl. G03F 7/00

(52) U.S. Cl. CPC G03F 7/70875

(57) ABSTRACT

A substrate treatment apparatus according to an aspect of the present invention includes: a support plate that supports a substrate and is provided with a heater member for heating the substrate; and a cooling unit for forcedly cooling the support plate, wherein the cooling unit includes: a cooling housing to provide a cooling space; a plurality of gas feed nozzles that is arranged in the cooling housing and supplies cooling gas toward the heater member; and a plurality of gas feed lines that is directly connected to the gas feed nozzles and supplies the cooling gas transferred from the outside to the gas feed nozzles.

### CROSS-REFERENCE TO RELATED APPLICATION

This application claims priority to and the benefit of Korean Patent Application No. 10-2022-0136609, filed on Oct. 21, 2022, the disclosure of which is incorporated herein by reference in its entirety.

### BACKGROUND OF THE INVENTION

### 1. Field of the Invention

The present invention relates to an apparatus for treating a substrate in order to heat and cool the substrate, and a method for improving cooling efficiency of the substrate treatment apparatus.

### 2. Description of the Related Art

A variety of substrate treatment apparatuses is now being used to conduct different processes for manufacturing semiconductor elements. Among such semiconductor processes, a photo-lithography process is a process of forming desired photoresist patterns on a substrate. Such a photo-lithography process as described above may mainly include a coating process, a heat treatment process, an exposure process and a developing process, and is performed using a plurality of devices. The photo-lithography process determines integrity of semiconductor elements, therefore, is appreciated as a reference for determining an ability of the semiconductor manufacturing process.

In recent years, for high density integration and improvement of productivity of semiconductor elements, the coating process, the heat treatment process and the developing process are being combined in a single photo-track apparatus for automation. Further, an exposure apparatus is also configured to be arranged with the photo-track apparatus in the in-line manner and thus can conduct the above-described processes continuously, thus greatly improving productivity.

After forming a liquid film on a substrate in the photo-lithography process, a baking process for heating the substrate comes into operation. The baking process is conducted at a very high temperature compared to room temperature, and for this purpose, a heater for heating the substrate is used. The heating temperature needs to be adjusted on the basis of the baking process in a bake chamber. When it requires to change the temperature to a level lower than that in the proceeding baking process, the heater may be cooled using a cooling means present below the heater. Since each of the processes is conducted in succession within the photo-track apparatus, shortening a cooling time of the heater may lead to reduction in the baking processing time. Accordingly, a technique for reducing the heater cooling time is now required.

### SUMMARY OF THE INVENTION

### Technical Problem

Therefore, the present invention has been made to overcome the afore-mentioned problems, and it is an object of the present invention to provide a substrate treatment apparatus capable of reducing a heater cooling time, as well as a method for improving cooling efficiency of the substrate treatment apparatus.

It is another object of the present invention to provide a substrate treatment apparatus that can increase heat-exchange efficiency between a cooling unit and surrounding spaces, as well as a method for improving cooling efficiency of the substrate treatment apparatus.

However, the above objects are only for illustrative and the scope of the present invention is duly not restricted by the same.

### Technical Solution

In order to achieve the above objects, the substrate treatment apparatus according to an aspect of the present invention may include: a support plate that supports a substrate and is provided with a heater member for heating the substrate; and a cooling unit for forcedly cooling the support plate, wherein the cooling unit may include: a cooling housing to provide a cooling space; a plurality of gas feed nozzles that is arranged in the cooling housing and supplies cooling gas toward the heater member; and a plurality of gas feed lines that is directly connected to the gas feed nozzles and supplies the cooling gas transferred from the outside to the gas feed nozzles.

According to the substrate treatment apparatus, the cooling housing may have a cylindrical shape with open top.

According to the substrate treatment apparatus, the gas feed nozzle may be connected to the gas feed line through the bottom surface of the cooling housing.

According to the substrate treatment apparatus, the gas nozzle may discharge the cooling gas in up-slanting direction at a position lower than the support plate toward the bottom surface of the support plate.

According to the substrate treatment apparatus, one of the gas feed nozzles may be connected to one of the gas feed lines.

According to the substrate treatment apparatus, a flow rate of the cooling gas supplied from the gas feed line to the gas feed nozzle may be independently controlled.

According to the substrate treatment apparatus, the gas feed line may be provided to be connected to an external gas supply means and to receive the cooling gas therefrom, wherein the number of the gas feed lines may be larger than the number of the gas supply means, and the gas supply means and the gas feed lines may be connected by 1:1 or 1:multiple.

According to the substrate treatment apparatus, the plurality of the gas feed nozzles may be dividedly arranged on a plurality of cooling areas having different radii from the center of the cooling housing.

According to the substrate treatment apparatus, the gas feed line may be provided to be connected to the external gas supply means and to receive the cooling gas therefrom, wherein the gas feed line connected to the gas feed nozzle disposed in the same cooling area may be connected to the same gas supply means.

According to the substrate treatment apparatus, the flow rate of the cooling gas may be independently controlled in each cooling area.

According to the substrate treatment apparatus, a heat capacity of the cooling housing may range from 100 to 200% relative to a heat capacity of the support plate.

According to the substrate treatment apparatus, a ratio of volume to surface area of the cooling housing may be controlled to match the heat capacity with that of the support plate.

According to the substrate treatment apparatus, the cooling housing may be provided with a plurality of uneven parts at a lateral side thereof.

According to the substrate treatment apparatus, the uneven part provided in a region having a larger radius may have a smaller surface area than that of the uneven part provided in another region having a smaller radius.

In order to achieve the above objects, the method for improving cooling efficiency of the substrate treatment apparatus according to another aspect of the present invention is provided to improve the cooling efficiency of the substrate treatment apparatus, and is characterized in that the substrate treatment apparatus may include: a support plate that supports a substrate and is provided with a heater member for heating the substrate; and a cooling unit for forcedly cooling the support plate, wherein the cooling unit may include: a cooling housing to provide a cooling space; a plurality of gas feed nozzles that is arranged in the cooling housing and supplies cooling gas toward the heater member; and a plurality of gas feed lines to supply the cooling gas transferred from the outside to the gas feed nozzles, wherein the plurality of gas feed lines may be directly connected to the gas feed nozzles.

According to the method for improving cooling efficiency of the substrate treatment apparatus (abbrev. to “the cooling efficiency improving method”), the cooling housing may have a cylindrical shape with open top, and the gas feed nozzle and the gas feed line may be connected through the bottom surface of the cooling housing.

According to the cooling efficiency improving method, a ratio of volume to surface area of the cooling housing may be adjusted such that a heat capacity of the cooling housing is being in the range of 100 to 200% relative to a heat capacity of the support plate.

According to the cooling efficiency improving method, the cooling housing may be provided with a plurality of uneven parts at a lateral side thereof.

According to the cooling efficiency improving method, it is possible to adjust a pattern interval and/or a pattern thickness of the uneven parts such that the heat capacity of the cooling housing is being in the range of 100 to 200% relative to the heat capacity of the support plate.

In order to achieve the above objects, the substrate treatment apparatus according to yet another aspect of the present invention may include: a support plate that supports a substrate and is provided with a heater member for heating the substrate; and a cooling unit for forcedly cooling the support plate, wherein the cooling unit may include: a cooling housing that provides a cooling space and has a cylindrical shape with open top; a plurality of gas feed nozzles that is arranged in the cooling housing and supplies cooling gas toward the heater member; and a plurality of gas feed lines that is directly connected to the gas feed nozzles and supplies the cooling gas transferred from the outside to the gas feed nozzles, and
wherein the gas feed nozzles and the gas feed lines may be connected through the bottom surface of the cooling housing wherein one of the gas feed nozzles is connected to one of the gas feed lines; a flow rate of the cooling gas supplied from the gas feed lines to the gas feed nozzles may be independently controlled; a ratio of volume to surface area of the cooling housing may be adjusted such that a heat capacity of the cooling housing is being in the range of 100 to 200% relative to a heat capacity of the support plate, thereby matching with the heat capacity of the support plate; and the cooling housing may be provided with a plurality of uneven parts at a lateral side thereof.

### Effect of Invention

According to one embodiment of the present invention completed as described above, a cooling time of the heater can be reduced.

Further, according to one embodiment of the present invention, heat-exchange efficiency between the cooling unit and surrounding spaces can be increased.

Of course, the scope of the present invention is duly not limited to such effects as described above.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a schematically perspective view showing a substrate treatment equipment according to one embodiment of the present invention;

FIG. 2 is a schematically cross-sectional view of the substrate treatment equipment in FIG. 1;

FIG. 3 is a schematic plan view of the substrate treatment equipment in FIG. 1;

FIG. 4 is a schematic plan view showing one example of a heat treatment chamber in FIG. 3;

FIG. 5 is a schematically front-side view of the heat treatment chamber in FIG. 4;

FIG. 6 is a schematically cross-sectional view of a heating device in FIG. 5;

FIG. 7 is a schematic plan view of a substrate support unit in FIG. 6;

FIG. 8 is a schematically exploded view showing a substrate treatment apparatus according to a comparative example;

FIG. 9 is a schematically exploded view showing a substrate treatment apparatus according to one embodiment of the present invention;

FIG. 10 is a schematically cross-sectional view showing a substrate support unit and a substrate treatment apparatus according to one embodiment of the present invention;

FIG. 11 schematically shows a connection form of a gas feed nozzle and a gas feed line according to another embodiment of the present invention;

FIG. 12 is a graph showing the cooling time of a substrate treatment apparatus according to each of the comparative example and one embodiment of the present invention;

FIG. 13 is a schematically exploded view of a substrate treatment apparatus according to another embodiment of the present invention;

FIG. 14 is a schematically cross-sectional view showing a substrate support unit and a substrate treatment apparatus according to another embodiment of the present invention;

FIG. 15 is a schematically cross-sectional view showing a method for controlling a heat capacity by altering uneven parts in FIG. 14; and

FIG. 16 shows a cooling capacity before and after applying the uneven parts in FIG. 14.

### DETAILED DESCRIPTION OF THE INVENTION

Hereinafter, different preferred embodiments of the present invention will be described in detail with reference to the accompanying drawings.

The embodiments of the present invention are provided to more completely describe the present invention to persons having ordinary knowledge in the art to which the present invention pertains (“those skilled in the art”), the following embodiments may be modified into different forms, and the scope of the present invention is duly not restricted to the following embodiments. On the contrary, these embodiments will be provided to further sufficiently and completely prepare the present disclosure and to perfectly inform those skilled art with the spirit of the present invention. In addition, a thickness or size of each layer shown in the figures will be exaggerated for convenience and clarity of the explanation.

Hereinafter, the embodiments of the present invention will be described with reference to the drawings in which ideal embodiments of the present invention are schematically illustrated. With regard to the drawings, for example, modification of the illustrated shapes may be expected on the basis of manufacturing techniques and/or tolerance.

Accordingly, the embodiments of the present inventive spirit should not be construed as limitation to specific morphologies in the section illustrated in the specification, for example, should include a change in morphologies caused during manufacturing.

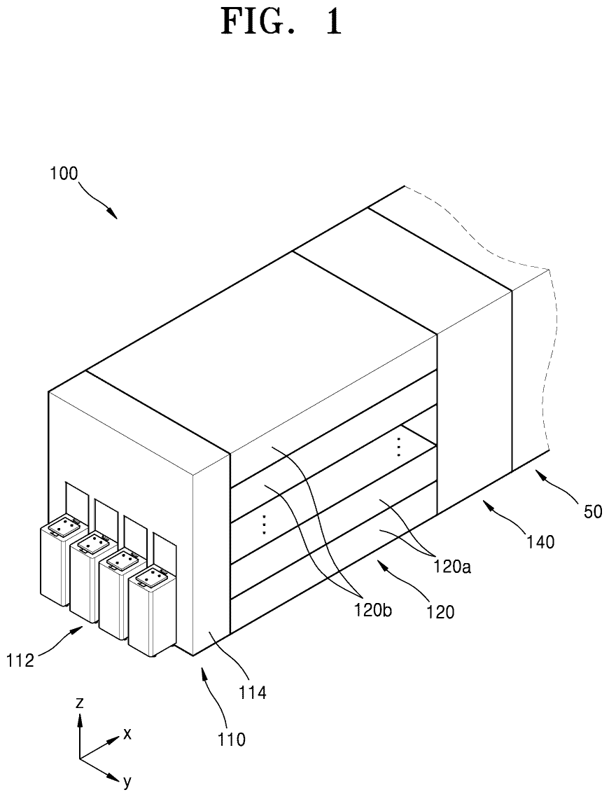

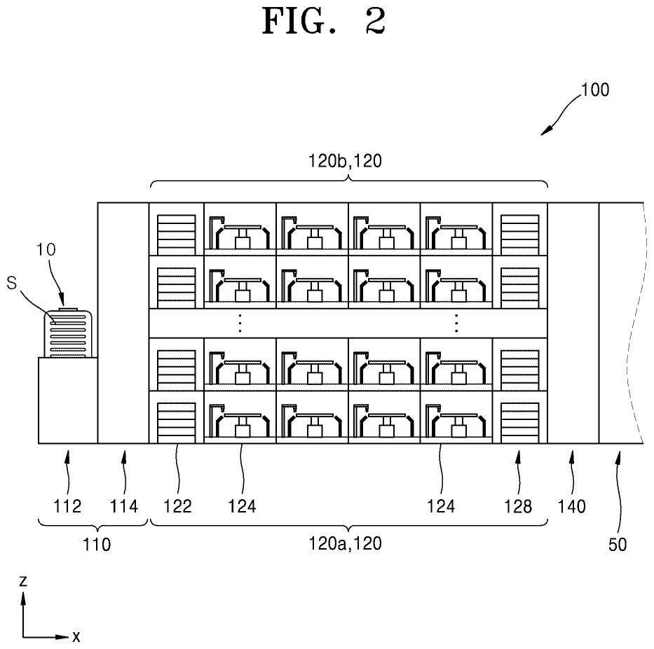

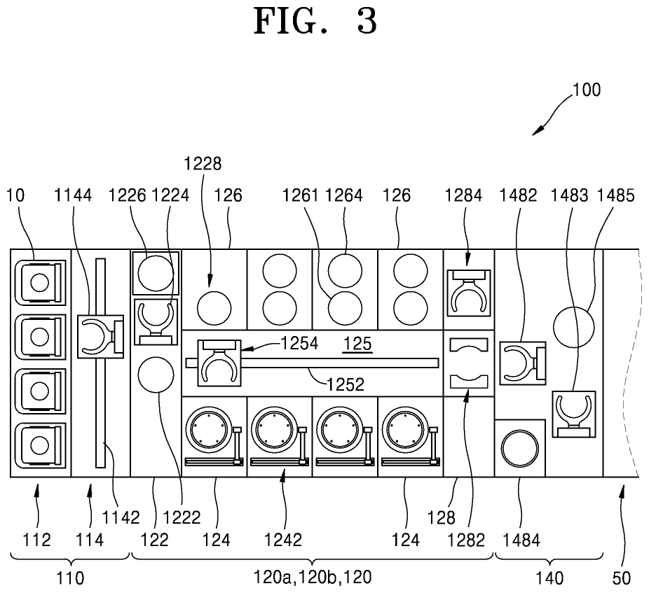

FIG. 1 is a schematically perspective view showing a substrate treatment equipment 100 according to one embodiment of the present invention, FIG. 2 is a schematically cross-sectional view of the substrate treatment equipment 100 in FIG. 1, and FIG. 3 is a schematic plan view of the substrate treatment equipment 100 in FIG. 1.

Referring to FIGS. 1 to 3, the substrate treatment equipment 100 may include an index module 110, a processing module 120 and an interface module 140.

In some embodiments, the index module 110, the processing module 120 and the interface module 140 may be sequentially aligned in series. For example, the index module 110, the processing module 120 and the interface module 140 are aligned in series in x-axis direction, wherein a width direction on a plane may become y-axis direction while a vertical direction may become z-axis direction.

More specifically, the index module 110 may be provided in order to transport a substrate S from a container 10 in which the substrate S is received. For example, the substrate S may be loaded from the container 10 in the index module 110 and transported to the processing module 120, while the completely treated substrate S may be received in the container 10 again.

The index module 110 may include a loading port 112 and an index frame 114. The loading port 112 may be disposed on a front end of the index module 110 and may be used as a port on which the container 10 including the substrate S for loading and/or unloading the substrate S is placed. The loading port 112 may be appropriately selected, for example, a plurality of loading ports 112 may be arranged in the y-axis direction.

In some embodiments, the container 10 used herein may include a sealed type container such as Front Open Unified Pod (FOUP). Inside the container 10, a plurality of substrates S, for example, wafers may be received. The container 10 may be placed in the loading port 112 by means of a transportation device (not shown) such as overhead transfer, overhead conveyor or automatic guided vehicle, robots, etc. in a factory, or by a worker.

Inside the index frame 114, an index robot 1144 may be disposed. For example, the index robot 1144 may move on a guide rail 1142 installed in the index frame 114. The index robot 1144 may be configured to move forward and backward, rotate, ascend and/or descend.

The processing module 120 may be provided to perform a coating process and a developing process for the substrate S. For example, the processing module 120 may include a coating block 120a in which the coating process is conducted on the substrate S and a developing block 120b in which the developing process is conducted on the substrate S.

The coating block 120a may be provided in the form of at least one layer. In some embodiments, a plurality of coating blocks 120a may be provided in the form of multiple layers laminated to one another. For example, the coating blocks 120a may have substantially the same structure in order to perform substantially the same process. The developing block 120b may be provided in the form of at least one layer. In some embodiments, a plurality of developing blocks 120b may be provided in the form of multiple developing blocks laminated to one another. For example, the developing blocks 120b may have substantially the same structure in order to perform substantially the same process.

Further, the coating blocks 120a and the developing blocks 120b may be laminated to each other. For example, the developing blocks 120b may be laminated on the coating blocks 120a. For another example, it is possible to laminate the coating blocks 120a on the developing blocks 120b, or to laminate the coating blocks 120a and the developing blocks alternately.

In some embodiments, each of the coating block 120a and the developing block 120b may include a front buffer chamber 122, a liquid treatment chamber 124, a transport chamber 125, a heat treatment chamber 126, and/or a rear buffer 128. The heat treatment chamber 126 may be provided to perform the cooling process and the heating process. The coating block 120a and the developing block 120b may generally have similar structures, however, may also be differently configured according to detailed functions thereof.

The liquid treatment chamber 124 in the coating block 120a may be provided to supply a liquid to the substrate S in order to form a coating layer. For example, the coating layer may include a photoresist layer, an anti-reflective layer, or the like. The liquid treatment chamber 124 in the developing block 120b may be used to supply a developing solution to the substrate S in order to etch a portion of the photoresist layer, thus forming a photoresist pattern.

The transport chamber 125 may be disposed between the heat treatment chamber 126 and the liquid treatment chamber 124 in order to transport the substrate S between the heat treatment chamber 126 and the liquid treatment chamber 124 within the coating block 120a and the developing block 120b. For example, the transport chamber 125 may be arranged such that a length direction thereof is in parallel to x-axis direction.

A transport robot 1254 may be disposed in the transport chamber 125, wherein the transport robot 1254 may be movably arranged on a guide rail 1252. The transport robot 1254 may transport the substrate S between the front buffer chamber 122, the liquid treatment chamber 124, the transport chamber 125, the heat treatment chamber 126, and/or the rear buffer chamber 128. For example, the transport robot 1254 may be configured to enable movement forward or backward, rotation, ascending and/or descending.

In some embodiments, the liquid treatment chamber 124 may be provided in plural. The liquid treatment chambers 124 may be arranged in the length direction of the processing module 120, that is, x-axis direction. At least some of the liquid treatment chambers 124 may perform liquid treatment processes different from one another. For example, each of the liquid treatment chambers 124 may be provided with a liquid treatment unit 1242, wherein the liquid treatment unit 1242 may include a substrate support part to rotate the substrate S while supporting the same, and a liquid injection part capable of injecting the liquid over the substrate S.

In some embodiments, the liquid treatment chamber 126 may be provided in plural. The liquid treatment chambers 126 may be arranged in the length direction of the processing module 120, that is, x-axis direction. At least some of the liquid treatment chambers 126 may perform liquid treatment processes different from one another. At least some of the heat treatment chambers 126 may include each cooling unit 1261 and heating unit 1264 inside the housing. Furthermore, some of the heat treatment chambers 126 may include each transport plate (not shown) installed therein in order to transport the substrate S between the cooling unit 1261 and the heating unit 1264.

The front buffer chamber 122 may be provided in each of the coating block 120a and the developing block 120b in order to receive the substrate S transported from the index module 110. For example, a plurality of front buffer chambers 122 may be laminated in the processing module 120. Inside each front buffer chamber 122, a cooling part 1222 in which the substrate S transported from the index module 110 is received or cooled may be provided. Further, inside the front buffer chamber 122, a loading robot 1224 for loading and/or unloading the substrate S may be disposed.

A plurality of seating plates or cooling plates may be disposed inside the cooling part 1222. For example, an index robot 1144 of an index frame 114 may load the substrate S from the container 10 and then place the same inside the cooling part 1222. The cooling part 1222 may impart a function of temporarily storing the substrates in addition to cooling the same, therefore, may also be called a buffer part.

The rear buffer chamber 128 may play a role of temporarily storing the substrate S between the processing module 120 and an interface module 140. For example, a plurality of rear buffer chambers 128 may be laminated in the processing module 120. In each rear buffer chamber 128, a buffer part 1282, in which the substrate S is seated, and a buffer robot 1284 for transporting the substrate S may be disposed.

The interface module 140 may connect the processing module 120 to an external exposure device 50, and thus provide an interface for sending and receiving the substrate S between the processing module 120 and the exposure device 50. For example, the interface module 140 may include an additional chamber 1484, an interface buffer 1485, and transport robots 1482 and 1483 therein.

In some embodiments, the additional chamber 1484 may conduct a predetermined additional process before carrying the substrate S completed in the coating block 120a to the exposure device 50, or the predetermined additional process before carrying the substrate S completed in the exposure device 50 to the developing block 120b. For example, the additional process may include an edge exposure process to expose an edge region of the substrate S, a top surface washing process to wash a top surface of the substrate S, or a bottom surface washing process to wash a bottom surface of the substrate S. Furthermore, a fan-filter unit (not shown) to form a downstream therein may be added at the top end of the interface module 140.

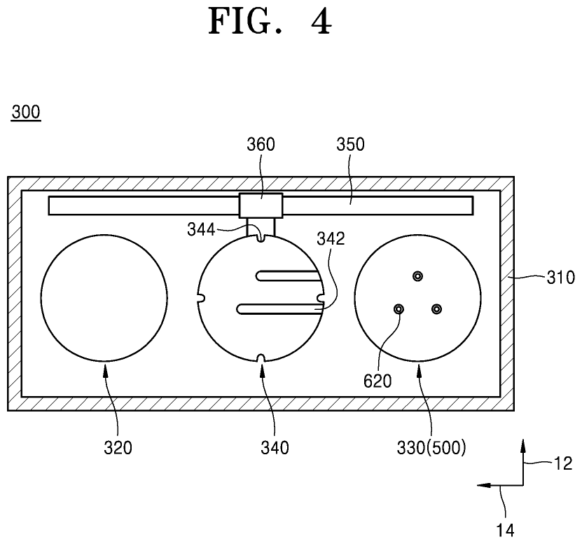

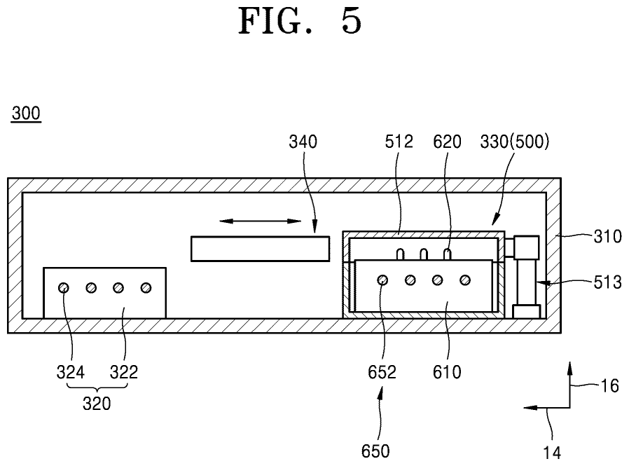

FIG. 4 is a schematic plan view showing one example of the heat treatment chamber 300 in FIG. 3. FIG. 5 is a schematically front view of the heat treatment chamber 300.

Hereinafter, the heat treatment chamber 126 of FIG. 3 is described with a heat treatment chamber 300 as an example. The cooling unit 1261 and the heating unit 1264 of FIG. 3 are described with a cooling device 320 and a heating device 330 as examples thereof. Further, the heat treatment chamber 300 is provided with a housing 310, the cooling device 320, the heating device 330 and a carrying plate 340.

The housing 310 is generally provided in a rectangular shape. An entrance (not shown) for entering and discharging a substrate W is formed on a lateral wall of the housing 310, and a door (not shown) for opening and closing the entrance may be provided. The cooling device 320, the heating device 330 and the carrying plate 340 may be provided inside the housing 310. The cooling device 320 and the heating device 300 may be provided side by side in a second direction 14. According to one example, the cooling device 320 may be positioned closer to the transport chamber 125, as compared to the heating device 330.

The cooling device 320 may have a cooling plate 322. The cooling plate 322 may generally have a circular shape from a top view. The cooling plate 322 may be provided with a cooling member 324. According to one example, the cooling member 324 may be formed inside the cooling plate 322, and may be provided as a flow-path through which a cooling fluid flows.

The heating device 330 may be provided as a heating unit 500 that heats the substrate to a temperature higher than room temperature. The heating device 330 may heat the substrate W in a normal pressure or lower reduced pressure atmosphere.

The carrying plate 340 is generally provided in a disc shape and may have a diameter corresponding to the substrate W. At a periphery of the carrying plate 340, a notch 344 is formed. The notch 344 may have a shape corresponding to a protrusion formed at a hand of the carrying robot 1254. When up and down positions of the hand and the carrying plate 340 are changed at a position where the hand of the transport robot 1254 and the carrying plate 340 are aligned up and down in a vertical direction, the substrate W may be delivered between the hand and the carrying plate 340. The carrying plate 340 may be mounted on a guide rail 350 and move along the guide rail 350 by a driver 360. The carrying plat 340 may be provided with a plurality of guide grooves 342 in a slit shape. The guide groove 342 may extend from an end of the carrying plate 340 to the inside thereof. The guide groove 342 has a length direction provided along a second direction 14, while the plural guide grooves 342 may be positioned to be spaced apart from one another in a first direction 12. The guide groove 342 may prevent the carrying plate 340 and a lift pin 620 from interfering each other when the substrate W is transferred between the carrying plate 340 and the heating device 330.

The substrate W is heated while directly placing the substrate W on a support plate 610, and is cooled in a state that the carrying plate 340 including the substrate W placed thereon is in contact with the cooling plate 322. The carrying plate 340 may be made of a material having a high heat transfer rate so that heat transfer is well done between the cooling plate 322 and the substrate W. According to one embodiment, the carrying plate 340 may be made of a metal material.

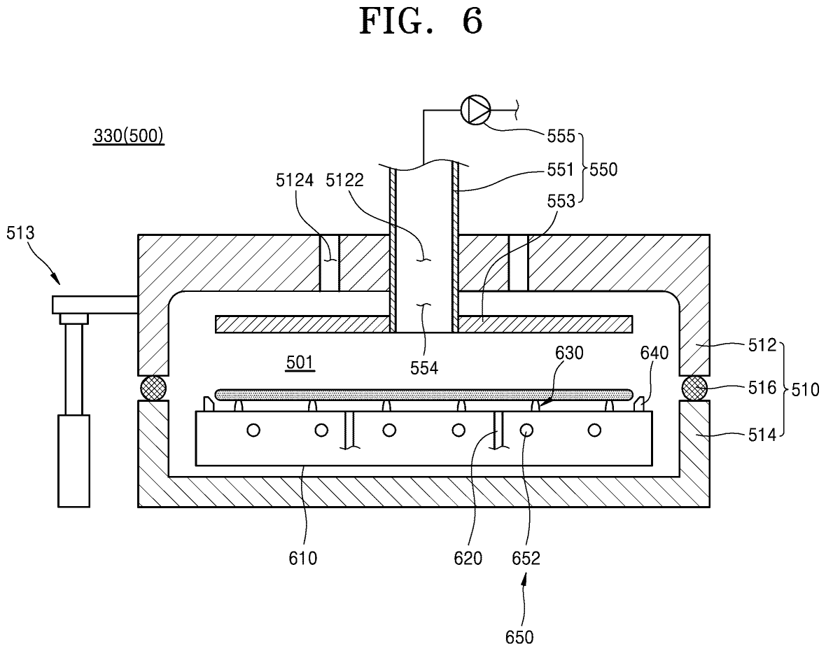

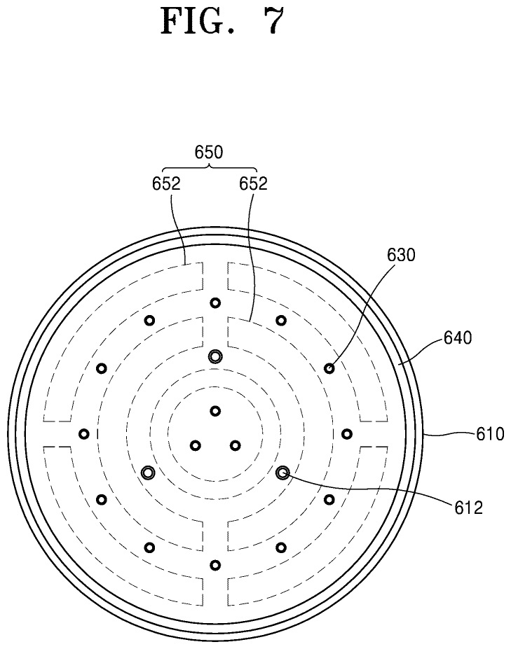

FIG. 6 is a schematically cross-sectional view showing the heating device 330 in FIG. 5. FIG. 7 is a schematic plan view showing the substrate support unit in FIG. 6.

Referring to FIG. 6, the heating device 350 is provided as a heating unit 500, wherein the heating unit 500 may include a housing 510 and an exhaust unit 550. The heating unit 500 may further include a substrate treatment apparatus 1000 including the support plate 610 described below inside a treatment space 501.

The housing 510 may impart the treatment space 501 to heat and treat the substrate W therein. The treatment space 501 may be provided as a space shielded from the outside. The housing 510 may include an upper body 510, a lower body 514 and a sealing member 516.

The upper body 512 may be provided in a barrel shape having open top. On the top surface of the upper body 512, an exhaust hole 5122 and an input hole 5124 are formed. The exhaust hole 5122 may be formed in the center of the upper body 512. The exhaust hole 5122 may exhaust the atmosphere of the treatment space 501. A plurality of input holes 5124 may be provided to be spaced apart from one another, and may be arranged to surround the exhaust hole 5122. The input holes 5124 may flow external air current into the treatment space 501. According to one embodiment, the external air current may be air, non-active gas, etc.

The lower body 514 may be provided in a barrel shape having open top. The lower body 514 is positioned under the upper body 512. The upper body 512 and the lower body 514 may be combined together to form the treatment space 501 therein. That is, a top end of the lower body 514 may be positioned to be opposed to a bottom end of the upper body 512.

One of the upper body 512 and the lower body 514 moves to an open position and a closed position by a lift member 513, while the other one is fixed at a predetermined position. The open position is a position at which the upper body 512 and the lower body 514 are spaced from each other to thus open the treatment space 501. On the other hand, the closed position is a position at which the treatment space 501 is closed against the outside by the lower body 514 and the upper body 512.

The sealing member 516 is positioned between the upper body 512 and the lower body 514. The sealing member 516 allows the treatment space to be sealed from the outside when the upper body 512 and the lower body 514 are in contact with each other. The sealing member 516 may be provided in an annular ring shape. The sealing member 516 may be fixed and coupled to the top end of the lower body 5140.

Referring to FIG. 7, the substrate support unit may include a support plate 610, a lift pin 620, a support pin 630, and a guide 640.

The support plate 610 may be provided in a circular plate shape. A top surface of the support plate 610 may have a larger diameter than the substrate W. Lift holes 612 may be arranged to surround the center of the top surface of the support plate 610 from the top view. The lift holes 612 may be arranged to be spaced apart from one another in a circumferential direction.

The lift pin 620 may move the substrate W up and down on the support plate 610. The lift pin 620 is provided in plural, wherein each may be provided in a pin shape to face up and down in a vertical direction. The lift pin 620 may be positioned in each lift hole 612. A driving member (not shown) may move the lift pins 620 between an ascending position and a descending position. The driving member (not shown) may be a cylinder.

The support pin 630 may prevent the substrate W from directly contacting a seating face of the support plate 610. The support pin 630 may be provided in a pin shape having a length direction parallel to the lift pin 620. The support pin 630 may be provided in plural, each of which may be mounted and fixed to the support plate 610. The support pins 630 may be positioned to protrude upward from the support plate 610. A top end of the support pin 630 is provided as a contact face in directly contact with the bottom surface of the substrate W, wherein the contact face has a convex-up shape. Therefore, a contact area between the support pin 630 and the substrate W can be minimized.

The guide 640 may guide the substrate W to be placed in a regular position thereof. The guide 640 may have a larger diameter than the substrate W. An inner side of the guide 640 may have a down-slanting shape toward a center axis of the support plate 610. Therefore, the substrate W extending to the inner side of the guide 640 may move to its regular position along a slanted surface. Further, the guide 640 may prevent a little air current inflowing between the substrate W and the support plate 610.

The heater member 650 may heat and treat the substrate W placed on the support plate 610. The heater member 650 may be positioned at a height lower than the substrate W placed on the support plate 610. The heater member 650 may include a plurality of heaters 652. The heaters 652 may be positioned within the support plate 610. The heaters 652 may heat different areas of the support surface. A region of the support plate 610 corresponding to each of the heaters 652 from the top view may be provided as a plurality of heating zones. A temperature of each heater 652 is independently adjustable. For example, 15 heating zones may be present. Each heating zone may be subjected to measuring a temperature by a measurement member (not shown). The heaters 652 may be provided with printed patterns or heat wires. The heater member 650 may heat the support plate 610 to a processing temperature.

The exhaust unit 550 may forcedly exhaust the inside of the treatment space 501. The exhaust unit 550 may include an exhaust pipe 551 and a guide pipe 553. The exhaust pipe 551 may have a tubular shape such that a length direction faces up and down in a vertical direction. The exhaust pipe 551 may be positioned to penetrate an upper wall of the upper body 512. According to one embodiment, the exhaust pipe 551 may be positioned to be inserted into an exhaust hole 5122. That is, a bottom end of the exhaust pipe 551 is positioned inside the treatment space 501 while a top end of the exhaust pipe 551 is positioned outside the treatment space 501. At the top end of the exhaust pipe 551, a reduced pressure (or vacuum) member 555 is connected. The vacuum member 555 may act to reduce a pressure of the exhaust pipe 551. Therefore, the atmosphere of the treatment space 501 passes through a hollow hole 554 and the exhaust pipe 551 in sequential order, thereby being exhausted.

The guide pipe 553 may have a plate shape with the hollow hole 554 in the center thereof. The guide plate 553 may have a circular plate shape extending from the bottom end of the exhaust pipe 551. The guide plate 553 may be fixed and coupled to the exhaust pipe 551 such that the hollow hole 554 and the inside of the exhaust pipe 551 are communicated to each other. The guide plate 553 is positioned to face a support surface of the support plate 610 at top of the support plate 510. The guide plate 553 may be positioned higher than the lower body 514. According to one embodiment, the guide plate 553 may be positioned at a height facing the upper body 512. The guide plate 553 is positioned to overlap with the input hole 5124 from the top view, and has a diameter spaced from the inner side of the upper body 512. Therefore, a gap may be generated between a lateral end of the guide plate 553 and the inner side of the upper body 512 wherein the gap may be provided as a flow-path through which the air current inflowing via the input hole 5124 is supplied to the substrate W.

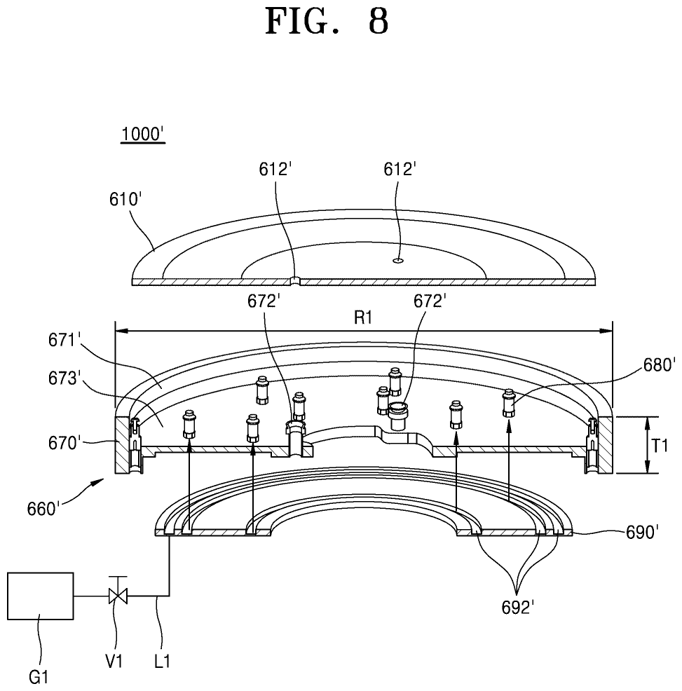

FIG. 8 is a schematically exploded view showing a substrate treatment apparatus 1000′ according to a comparative example.

The substrate treatment apparatus 1000′ of the comparative example includes a support plate 600′ and a cooling unit 660′. The support plate 610′ is substantially the same as the support plate 610 described above, and therefore a detailed description thereof will be omitted.

The cooling unit 660′ includes a cooling housing 670′, a gas feed nozzle 680′ and a gas dispenser 690′. The cooling unit 660′ cools the support plate 610′. The cooling unit 660′ supplies gas to the bottom surface of the support plate 610′ to cool the support plate 610′. That is, it forcedly cools a heater member (not shown) in the support plate 610′.

The cooling housing 670′ provides a cooling space therein. The cooling housing 670′ may be provided in approximately a cylindrical shape having open top. The cooling housing 670′ may include a lateral part 671′ and a bottom part 673′. The lateral part 671′ may be provided in a cylindrical shape at a predetermined thickness T1. The bottom part 673′ may be connected to a lower portion of the lateral part 671′ and may be provided along a horizontal direction.

The support plate 610′ may be disposed on the open top of the cooling housing 670′. Optionally, for insertion of the support plate 610′, a stepped part in response to a circumferential shape of the support plate 610′ may be formed at the top end of the lateral part 671′. When the support plate 610′ and the cooling housing 670′ are interconnected, a cooling space surrounded by the bottom surface of the support plate 670′, an inner side of the lateral part 671′ and the top surface of the bottom part 673′ may be provided. In order to insert the support plate 610′, the cooling housing 670′ preferably has a diameter R1 larger than a diameter of the support plate 610′, however, is not particularly limited thereto. The support plate 610′ may also be provided in a form to be placed on top of the cooling housing 670′.

On the bottom part 673′ of the cooling housing 670′, a lift path 672′ may be formed. The lift path 672′ may be provided as a passage through which the lift pin 620 passes. The lift path 672′ may be formed at a site corresponding to the lift hole 612′ of the support plate 610′.

A plurality of gas feed nozzles 680′ may be disposed inside the cooling housing 670′. Cooling gas (e.g., air) may be discharged toward the bottom surface of the support plate 610′. By discharging the cooling gas, a heater member (not shown) included in the support plate 610′ may be cooled.

On the other hand, the conventional cooling unit 660′ may include a gas dispenser 690′ further connected to the bottom of the cooling housing 670′. The gas dispenser 690′ may have a cooling gas dispensing pattern 692′ formed in a circumferential direction. The cooling gas dispensing pattern 692′ may be provided in plural in order to respond different radii. The gas dispensing pattern 692′ in a ring shape may be provided as a transfer passage of the cooling gas. On the top in third-direction 18 (that is, vertical top) of the cooling gas dispensing pattern 692′, a plurality of gas feed nozzles 680′ may be disposed. Therefore, the cooling gas in the gas dispensing pattern 692′ can move toward the gas feed nozzles 680′.

The gas dispenser 690′ receives the cooling gas transferred from an external gas supply means G1 via a gas feed line L1. The gas supply means G1 controls a feeding amount of cooling gas to the gas feed line L1 through a valve V1. One gas feed line L1 is connected to the gas dispenser 690′ and supplies the cooling gas into a space of the cooling gas dispensing pattern 692′. The cooling gas transferred through the gas feed line L1 moves toward the gas feed nozzle 680′ while filling the space of the cooling gas dispensing pattern 692′.

The substrate treatment apparatus 1000′ of the comparative example has an advantage in that cooling gas can be supplied using a single gas supply means G1 and a single gas feed line L1, or using a few of gas supply means and gas feed lines, however, also entails the following disadvantages.

First, there is a problem due to the heat member of the support plate 610′ that a temperature of the gas dispenser 690′ may also increase. Specifically, the support plate 610′ and the gas dispenser 690′ are disposed to be adjacent by a distance corresponding to approximately a thickness T1 of the cooling housing 670′. That is, when the temperature of the support plate 610′ is about 130° C., heat is transferred to surroundings, which in turn leads to an increase in temperature of the gas dispenser 690′ by about 65° C. after a lapse of sufficient time. In this state, when the cooling gas is transferred to the gas dispenser 690′, a temperature of the cooling gas is duly increased owing to the temperature of the gas dispenser 690′. If the cooling gas with increased temperature is discharged through the gas feed nozzle 680′, the cooling efficiency would be naturally lowered.

Second, in order to reduce the increase in temperature of the gas dispenser 690′ by keeping away a distance between the support plate 610′ and the gas dispenser 690′, the cooling housing 670′ must be configured to have a large thickness T1. In this case, a size of the cooling housing 670′ becomes increased to thus increase an inner cooling space and use a large amount of cooling gas, hence causing deterioration in efficiency. Furthermore, as the size of the cooling housing 670′ is large, a heat capacity of the housing itself becomes increased, which in turn causes again a problem of increasing the temperature of the cooling gas discharged to the cooling space. In addition, due to high heat capacity of the cooling housing 670′, heat emitting efficiency to the outside is also deteriorated.

Third, after the cooling gas is dispensed along the cooling gas dispensing pattern 692′ of the gas dispenser 690′, the cooling gas is supplied to each gas feed nozzle 680′ and thus deviation of temperature and deviation of flow rate may occur in each gas feed nozzle 680′. Therefore, the deviation of temperature per region may occur even in a process of cooling the bottom of the support plate 610′,

In order to solve the above problems, the substrate treatment apparatus 1000 of the present invention proposes a cooling gas supplying structure that can improve cooling efficiency.

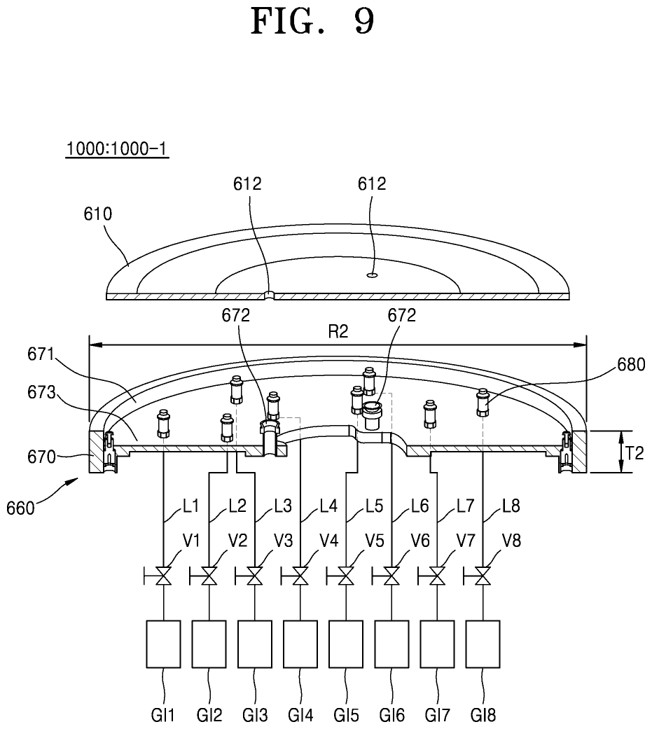

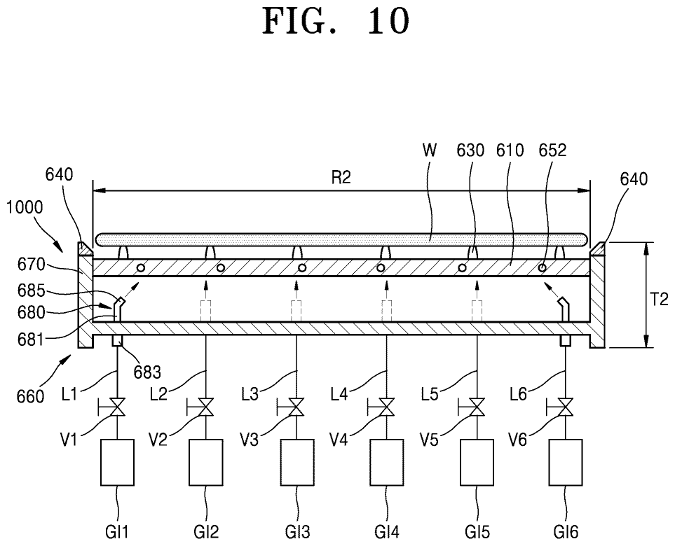

FIG. 9 is a schematically exploded view showing the substrate treatment apparatus (1000; 1000-1) according to one embodiment of the present invention. FIG. 10 is a schematically cross-sectional view showing the substrate support unit and the substrate treatment apparatus (1000; 1000-1) according to one embodiment of the present invention.

Referring to FIGS. 9 and 10, the substrate treatment apparatus (1000; 1000-1) of the present invention may include a support plate 610 and a cooling unit 660. The support plate 610 is substantially the same as described above through FIGS. 5 to 7, therefore, a detailed description thereof will be omitted. Further, a cooling housing 670 of the cooling unit 660 will be described in regard to a difference as compared to the cooling housing 670′ of the cooling unit 660′ as described in FIG. 8.

The cooling unit 660 may include the cooling housing 670 and a gas feed nozzle 680. A plurality of gas feed nozzles 680 may be disposed on the bottom part 673 of the cooling housing 670. The plurality of gas feed nozzle 680 may discharge the cooling gas (e.g., air) toward the bottom surface of the support plate 610. The gas feed nozzle 680 is positioned at a height lower than a heater member 650 of the support plate 610.

The gas feed nozzle 680 may include a main body 681, a line connector 683 and a discharging part 685. The main body 681 may provide a passage through which the transferred cooling gas moves, and may be formed to extend toward a third-direction (18, z-axis direction). The line connector 683 may be disposed on a lower end of the gas feed nozzle 680 and connected to a gas feed line (L; L1-L8). The discharging part 685 may provide an outlet (not shown) to discharge the cooling gas moved from the main body 681. For example, the discharging part 685 of the gas feed nozzle 680 may discharge the gas in up-slanting direction at a position lower than the heater member 650 toward the bottom surface of the heater member 650.

Further, unlike the comparative example in FIG. 8, the cooling unit 660 of the present invention does not include a gas dispenser 690′. In order to solve a problem when including the gas dispenser 690′, the present invention is characterized in that the gas feed nozzle 680 is directly connected to the gas feed line (L; L1-L8).

The gas feed nozzle 680 may communicate with the bottom part 673 of the cooling housing 679 so that the line connector 683 can be directly connected to the gas feed line (L; L1-L8). Each gas feed nozzle 680 may be connected to each gas feed line (L1-L8). FIG. 9 shows a state in which the illustrated eight (8) gas feed nozzles 680 are connected to eight (8) gas feed lines (L1-L8), respectively. FIG. 10 shows a state in which the illustrated six (6) gas feed nozzles 680 are connected to six (6) gas feed lines (L1-L6), respectively. The gas feed lines (L1-L8), respectively, may be connected to gas feed supply means (GI: GI1-GI8) and valves (V: V1-V8).

As compared to the comparative example, except for the gas dispenser 690′, since a thickness of the cooling housing 670 is reduced (T1->T2) as described below, it is possible to ensure each space of the gas feed line (L1-L8) connected to the gas feed nozzle 680.

Since each of the gas feed nozzles 680 is directly connected to each of the gas feed lines (L1-L8), the problem of the comparative example could be solved. The cooling gas moved through the gas feed lines (L1-L8) is instantly discharged through the gas feed nozzles 680, therefore, it is effective to prevent a problem of increasing the temperature before discharging the cooling gas by heat of the support plate 610.

Further, each of the gas feed lines (L1-L8) is connected to each of the gas supply means (GI1-GI8), and a feed flow rate of the cooling gas may be independently controlled by the valves (V1-V8). Although the number of the gas supply means (GI1-GI8) is not necessarily equal to the number of the gas feed lines (L1-L8), if the number of the valves (V1-V8) is equal to the number of the gas feed lines (L1-L8), the feed flow rate of the cooling gas may be independently controlled by only opening and closing (or switching) the valves (L1-V8). Accordingly, the present invention attains effects of solving such a problem that deviation of temperature and/or flow rate occurs in the gas feed nozzle 680′ due to the cooling gas dispensing pattern 692′ according to the comparative example, and effects of improving uniformity in the temperature and/or flow rate of the cooling gas to the bottom surface of the support plate 610.

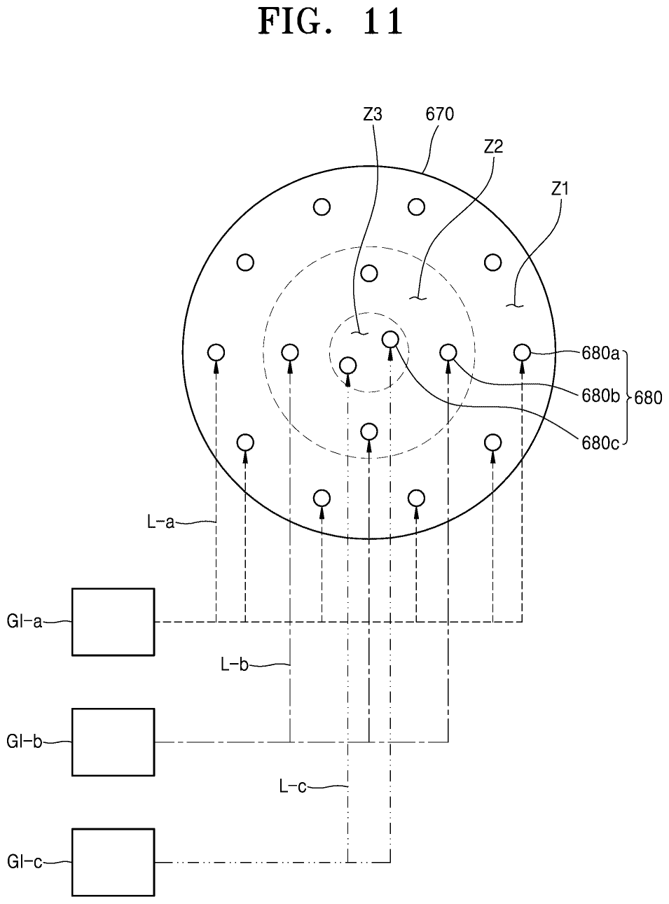

FIG. 11 schematically shows a connection manner of the gas feed nozzle 680 and the gas feed line according to another embodiment of the present invention.

Referring to FIG. 11, the support plate 610 may have a higher temperature in the center portion since a peripheral portion shows higher extent of discharging heat to the outside than the center portion. Therefore, in order to uniformly cool throughout the whole surface of the support plate 610, the gas feed nozzles (680: 680a, 680b, 680c) may be disposed in response to separate regions. A plurality of gas feed nozzles (680: 680a, 680b, 680c) may be dividedly disposed on a plurality of cooling regions (Z1-Z3) having different radii from the center of the cooling housing 670.

For example, the plurality of gas feed nozzle 680 may be disposed on a plurality of cooling regions (Z1-Z3) such as a peripheral region Z1, an inter-space region Z2, a center region Z3, etc. A gas feed nozzle 680a may be disposed in the peripheral region Z1. Likewise, another gas feed nozzle 680b may be disposed in the inter-space region Z2 while a further gas feed nozzle 680c may be disposed in the center region 680c. Since the temperature of the center portion of the support plate 610 is higher, a larger amount of cooling gas may be discharged toward the center region Z3, as compared to the peripheral region Z1.

In order to discharge much more cooling gas to the center region Z3 than the peripheral region Z1, it is possible to increase the number of batches per area of the gas feed nozzle 680c than the number of batches per area of the gas feed nozzle 680a. Otherwise, a valve may be controlled such that an amount of the cooling gas fed from the gas feed line (L-c) connected to the gas feed nozzle 680c is larger than an amount of the cooling gas fed from the gas feed line (L-a) connected to the gas feed nozzle 680a.

Alternatively, the number of the gas geed lines (L-a, L-b, L-c) connected to the external gas supply means (GI-a, GI-b, GI-c), respectively, may be different from the number of the gas feed nozzles 680. As shown in FIG. 11, for example, with regard to the peripheral region Z1, total eight (8) gas feed lines (L-a) are branched from a single gas supply means (GI-a) and may supply the cooling gas to eight (8) gas feed nozzles 680a. On the other hand, with regard to the inter-space region Z2, total four (4) gas feed lines (L-b) are branched from a single gas supply means (GI-b) and may supply the cooling gas to four (4) gas feed nozzles 680b. Furthermore, with regard to the center region Z3, total two (2) gas feed lines (L-c) are branched from a single gas supply means (GI-c) and may supply the cooling gas to two (2) gas feed nozzles 680c.

In other words, even when the gas feed nozzle 680 and the gas feed lines (L-a, L-b, L-c) are directly connected by 1:1, the number of the gas supply means (GI-a, GI-b, GI-c) may be less than the number of the gas feed lines (L-a, L-b, L-c). From another viewpoint, the gas supply means (GI-a, GI-b, GI-c) and the gas feed lines (L-a, L-b, L-c) may be connected by 1:1 or 1:multiple. From a further viewpoint, the gas feed lines (L-a, L-b, L-c) connected to the gas feed nozzles (680a, 680b, 680c) arranged in the same cooling region (Z1 to Z3) may be connected to the same gas supply means (GI-a, GI-b, GI-c). Accordingly, it is effective to simply implement a variety of connection configurations between the gas supply means (GI-a, GI-b, GI-c) and the gas feed lines (L-a, L-b, L-c).

Further, for each of the cooling regions (Z1-Z3), a feed flow rate of the cooling gas may be independently controlled. Even when the number of the gas supply means (GI-a, GI-b, GI-c) is not exactly equal to the number of the gas feed lines (L-a, L-b, L-c), if the number of the valves (V1 to V8) (see FIG. 9) is equal to the number of the gas feed lines (L-a, L-b, L-c), the feed flow rate of the cooling gas for each of the cooling regions (Z1-Z3) may be independently controlled by only switching the valve.

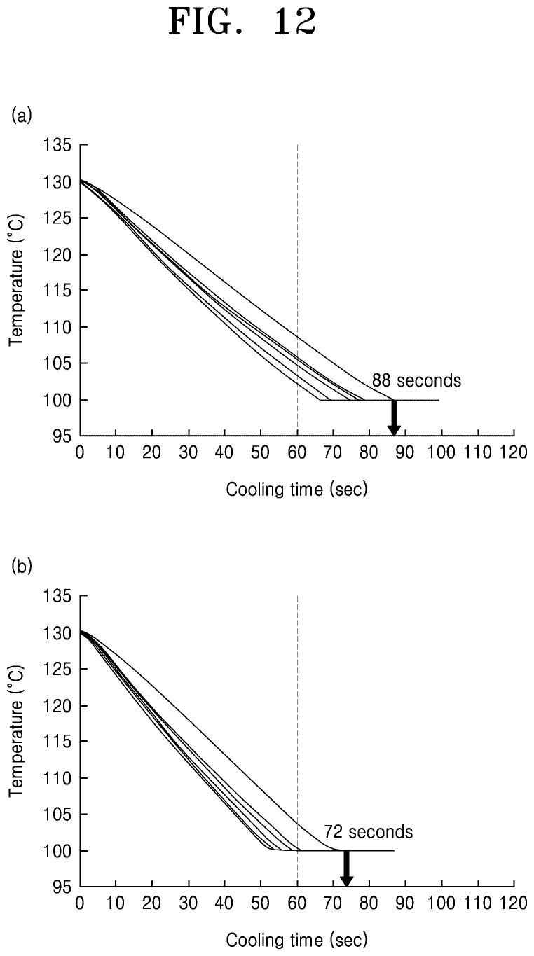

FIG. 12 is a graph showing a cooling time of each substrate treatment apparatus according to the comparative example in FIG. 8 and one embodiment of the present invention. FIG. 12(a) exhibits the cooling time according to the comparative example in FIG. 8, FIG. 12(b) exhibits the cooling time according to the embodiment of the present invention. At six (6) points of each cooling space, a temperature to cooling time was measured.

Referring to FIG. 12(a), it was confirmed that about 88 seconds are needed to reduce the temperature of the support plate 610′ from 130° C. to 100° C. according to the comparative example in FIG. 8. On the other hand, referring to FIG. 12(b), it was confirmed that about 72 seconds are required to reduce the temperature of the support plate 610 from 130° C. to 100° C. according to the embodiment of the present invention. That is, there is an effect of shortening the time from about 88 seconds to 72 seconds by about 17%. As known by the above evaluated results, it could be confirmed that, rather than a method that the cooling gas is supplied to the gas feed nozzle 680′ after dispensing the cooling gas using the gas dispenser 690′, a method of supplying the cooling gas by directly connecting the gas feed line to the gas feed nozzle 680 can improve the cooling efficiency.

Meanwhile, the present invention is characterized in that the cooling efficiency can be improved by decreasing a heat capacity of the cooling housing 670 relative to a heat capacity of the support plate 610, as compared to the comparative example. By decreasing the heat capacity of the cooling housing 670 and making it to be sensitive to a change in temperature, the cooling housing 670 may receive a heat of the cooling gas, which was injected to the support plate 610 and took a heat of the heater member 650 to thus become hot, and then may release the heat to the outside.

The cooling housing 670 according to the embodiment of the present invention in FIG. 9 may be formed to have a thinner thickness T2 than a thickness T1 of the cooling housing 670′ according to the comparative example in FIG. 8. Since a size of the substrate W is not changed, a radius (R1, R2) of the cooling housing (670′, 670) may be the same in both of the comparative example and the embodiment of the present invention. Therefore, the heat capacity can be reduced by forming the cooling housing 670 with further thinner thickness T2.

By controlling a ratio of volume to surface area of the cooling housing 670, the heat capacity can be regulated. At this time, the heat capacity of the cooling housing 670 may range from 100 to 200% relative to the heat capacity of the support plate 610. In other words, the heat capacity of the cooling housing 670 may be at least equal to or even larger by 2 times the heat capacity of the support plate 610. If the heat capacity of the cooling housing 670 is smaller than the heat capacity of the support plate 610, a heat of the support plate 610 does not move well to the cooling plate 670, thus causing a decrease in cooling efficiency. On the contrary, when the heat capacity of the cooling housing 670 is larger than the heat capacity of support plate 610 by 2 times or more, the cooling housing 670 contains lots of heat to thus reduce a heat release rate to the outside. Therefore, a large amount of cooling gas must be used and thus the cooling efficiency is also reduced.

The following table exhibits the heat capacities according to the embodiment of the present invention as well as the comparative example.

TABLE 1

| | | | | Embodiment of | |
|---|---|---|---|---|---|
| | | Comparative | | the present | |
| | Support plate | example in FIG. 8 | | invention | |
| Material | AlN | Al | | Al | |
| Specific heat | 740 | 900 | | 900 | |
| (J/kg · K) | | | | | |
| Mass (kg) | 1.26 | 2.90 | | 1.5 | |
| Volume (mm³) | 382,320 | 1,072,659 | | 556,168 | |
| Surface area | 190,932 | 286,178 | | 304,169 | |
| (mm²) | | | | | |
| Heat capacity | 932 (100%) | 2,610 | (280%) | 1,350 | (145%) |
| (J/K) | | | | | |
| Surface | | 2.7 | (100%) | 5.5 | (204%) |
| area/volume | | | | | |

Compared to the comparative example in FIG. 8, the present invention has increased the surface area/volume by about 204% by decreasing the thickness T2 of the cooling housing 670. Further, the heat capacity was 145% matching relative to the support plate 610, as compared to 280% (comparative example).

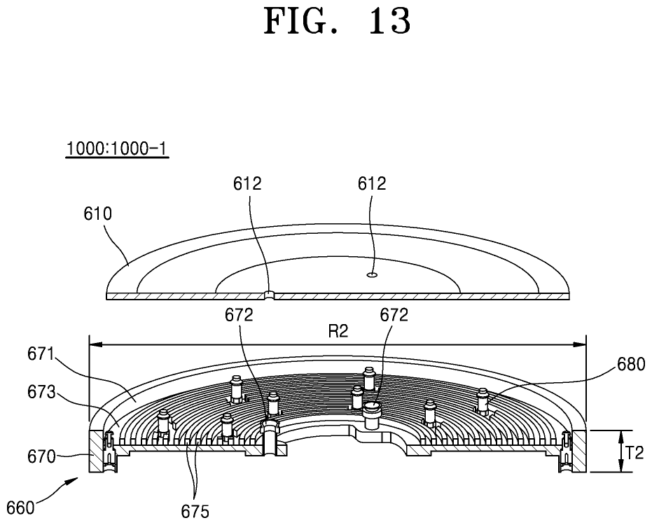

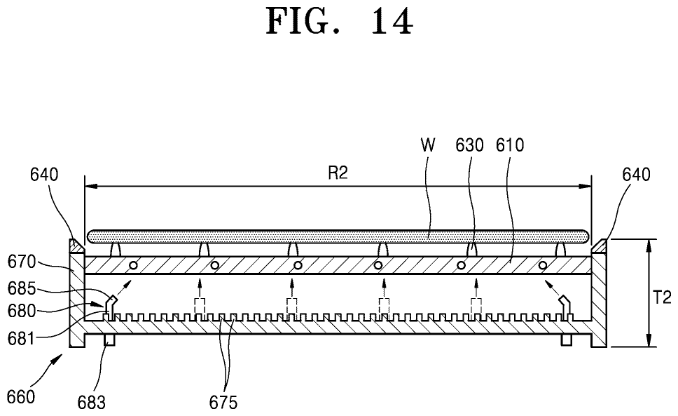

FIG. 13 is a schematically exploded view showing the substrate treatment apparatus (1000: 1000-2) according to another embodiment of the present invention. FIG. 14 is a schematically cross-sectional view showing a substrate support unit and the substrate treatment apparatus (1000: 1000-2) according to another embodiment of the present invention. Hereinafter, only differences from the substrate treatment apparatus (1000: 1000-2) shown in FIGS. 9 and 10 will be described.

Referring to FIGS. 13 and 14, the substrate treatment apparatus (1000: 1000-2) of the present invention may include a support plate 610 and a cooling unit 660. The cooling housing 670 may be provided with a plurality of uneven parts 675 at a lateral side thereof. Although FIGS. 13 and 14 show the uneven parts 675 formed on the bottom part 673, the above lateral side may be understood as a concept embracing an outer side, an inner side, a top side and a bottom side, etc. in addition to the bottom part 673 and the lateral side 671.

The plurality of uneven parts 675 may extend the surface area in the cooling housing 670 having the same volume. As shown in [Table 1] above, as the surface area/volume increases, the heat release rate may be enhanced and the cooling efficiency may be improved. The increase in surface area in the cooling space of the cooling housing 670 enables a heat of the cooling gas to be more easily transferred to the cooling housing 670. Further, an increase in external surface area of the cooling housing 670 enables the heat of the cooling housing 670 to be more easily released to the outside. If more uneven parts 675 are provided under the same volume condition to extend the surface area of the cooling housing 670, the cooling efficiency may be improved.

The plurality of uneven parts 675 may be formed such that a width and thickness of each pattern are in the range of mm unit, preferably in the range of 2 to 3 mm. However, within the range purposed of increasing the surface area, the size and/or shape of the uneven part 675 are not limited.

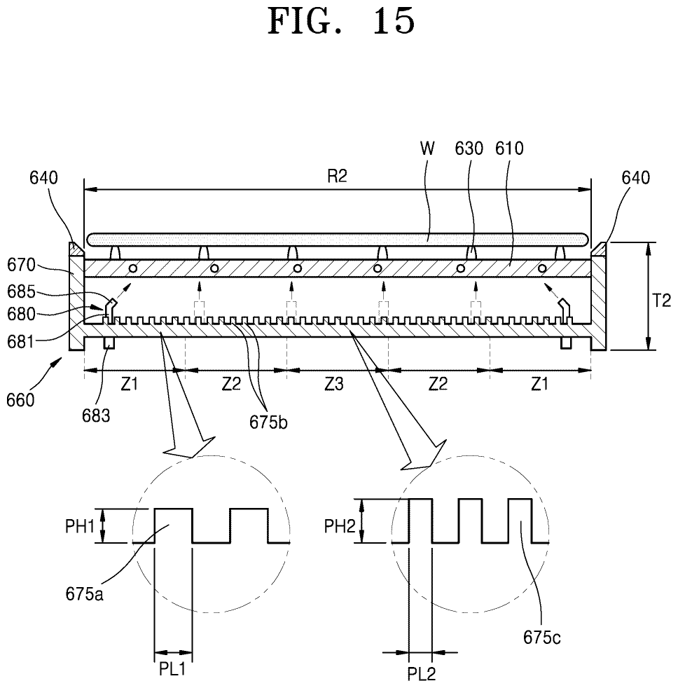

FIG. 15 is a schematically cross-sectional view showing a method for controlling a heat capacity by altering the uneven part 675 in FIG. 14.

As described above, the support plate 610 may have a higher temperature in the center portion than the periphery thereof. Therefore, it is advantageous that heat exchange is performed much more in the center portion in order to improve the cooling efficiency.

Referring to FIG. 15, the cooling housing 670 may have different sizes of uneven parts 675 in different regions thereof. Alternatively, the uneven parts 675 may be formed in only some of the regions.

An uneven part 675a provided in a region having a larger radius from the center of the cooling housing 670 may be formed to have a smaller surface area, as compared to the other region having a smaller radius. The center region Z3 should discharge heat much more than the peripheral region Z1, therefore, an uneven part 675c may be formed to have a surface area larger than the uneven part 675a by setting at least one among a pattern width PL2 and a height PH2 of the uneven part 675c to be different from a pattern width PL1 and a height PH1 of the uneven part 675a. For example, the pattern width PL2 of the uneven part 675c may be set to be smaller than the pattern width PL1 of the uneven part 675a, while the pattern height PH2 of the uneven part 675c may be set to be larger than the pattern height PH1 of the uneven part 675a.

Meanwhile, a change in surface area by the uneven part 675 may contribute to a change in heat capacity of the cooling housing 670. Therefore, it is possible to match the heat capacity of the cooling housing 670 with the heat capacity of the support plate 610 by altering the pattern width and pattern height of the uneven part 675. As described above, since the heat capacity can be controlled by, in addition to adjusting the thickness T2 of the cooling housing 670, changing the pattern width and pattern height of the uneven part 675, a variety of design ideas for the cooling housing 670 may be proposed.

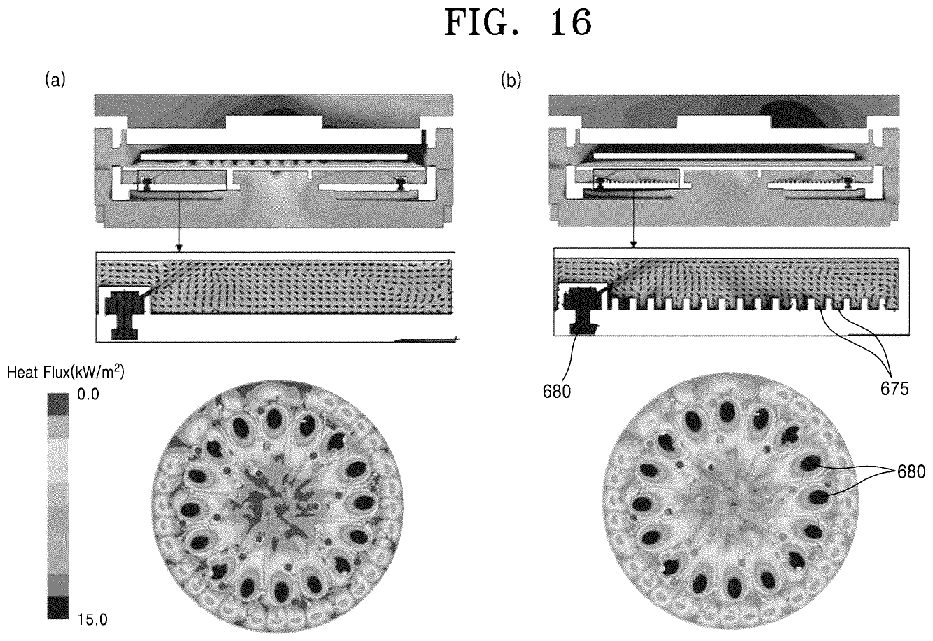

FIG. 16 exhibits cooling capacities before and after applying the uneven part 675 of FIG. 14. FIG. 16(a) shows the cooling capacity of the uneven part 675 before applying the uneven part 675, and FIG. 16(b) shows the cooling capacity of the uneven part 675 after applying the uneven part 675.

It could be confirmed that a heat flux value becomes close to 15 (kW/m²) by discharging the cooling gas in a position at which the gas feed nozzles 680 of the cooling housing 470 are disposed. Further, referring to FIG. 16(b) compared to FIG. 16(a), when the uneven part 675 is applied, it could be confirmed that the heat flux value is uniformly exhibited throughout the whole cooling space of the cooling housing 470. FIG. 16(a) shows a part of the center portion in which the heat flux is near to 0 (kW/m²), whereas FIG. 16(b) shows that even the center portion has mainly the heat flex in the range of 1.5 to 3.0 (kW/m²). FIG. 16(a) shows the cooling capacity of about 536 W while FIG. 16(b) shows the cooling capacity of about 567 W, therefore, it could be confirmed that the cooling capacity is increased by about 5.7% and the cooling uniformity is also improved.

As described above, the present invention has an effect of reducing a cooling time of a heater by directly connecting a gas feed nozzle and a gas feed line, matching a heat capacity of a cooling housing to correspond to a support plate, and applying an uneven part inside the cooling housing. Further, the present invention has also an effect of increasing heat exchange efficiency between a cooling unit and the surrounding space.

Although the present invention has been described with reference to the embodiments shown in the drawings, however, these are merely proposed for illustrative purposes and those skilled in the art will appreciate that various modifications and other equivalent embodiments are possible. Therefore, the technical and true range of the present invention to be protected would be defined on the basis of technical spirit disclosed in the appended claims.

### DESCRIPTION OF REFERENCE NUMERALS

100: Substrate treatment equipment
200: Substrate treatment apparatus
300: Heat treatment chamber
330 (500): Heating device (heating unit)
610: Support plate
620: Lift pin
630: Support pin
640: Guide
650: Heater member
660, 660′: Cooling unit
670, 670′: Cooling housing
675: Uneven part
680, 680′: Gas feed nozzle
690′: Gas dispenser
GI, GI1-GI8: Gas supply means
L, L1-L8: Gas feed line
V, V1-V8: Valve

What is claimed is:

1. An apparatus for treating a substrate (“substrate treatment apparatus”), comprising:
a support plate that supports the substrate and includes a heater member to heat the substrate; and
a cooling unit that forcedly cools the support plate,
wherein the cooling unit includes:
a cooling housing to provide a cooling space;
a plurality of gas feed nozzles that is disposed in the cooling housing and feeds the cooling gas toward the heater member; and
a plurality of gas feed lines that is directly connected to the gas feed nozzles to supply the cooling gas transferred from the outside to the gas feed nozzles.

2. The apparatus according to claim 1, wherein the cooling housing has a cylindrical shape with open top.

3. The apparatus according to claim 1, wherein the gas feed nozzles are connected to the gas feed lines through the bottom surface of the cooling housing.

4. The apparatus according to claim 3, wherein the gas feed nozzle discharges the cooling gas in up-slanting direction at a position lower than the support plate toward the bottom surface of the support plate.

5. The apparatus according to claim 3, wherein one of the gas feed nozzles is connected to one of the gas feed lines.

6. The apparatus according to claim 5, wherein a flow rate of the cooling gas supplied from the gas feed line to the gas feed nozzle.

7. The apparatus according to claim 3, wherein the gas feed line is provided to be connected to an external gas supply means and to receive the cooling gas transferred therefrom, and
the number of the gas feed lines is larger than the number of the gas supply means, and the gas supply means and the gas feed lines are connected by 1:1 or 1:multiple.

8. The apparatus according to claim 2, wherein the plurality of gas feed nozzles is dividedly disposed in a plurality of cooling regions having different radii from the center of the cooling housing.

9. The apparatus according to claim 8, wherein the gas feed line is connected to the external gas supply means to receive the cooling gas transferred therefrom, and
the gas feed line connected to the gas feed nozzle disposed in the same cooling region is connected to the above same gas supply means.

10. The apparatus according to claim 8, wherein the flow rate of the cooling gas is independently controlled in each of the cooling regions.

11. The apparatus according to claim 1, wherein a heat capacity of the cooling housing is in the range of 100 to 200% relative to a heat capacity of the support plate.

12. The apparatus according to claim 11, wherein a ratio of volume to surface area of the cooling housing is controlled to match the heat capacity of the cooling housing with that of the support plate.

13. The apparatus according to claim 2, wherein a plurality of uneven parts is provided on a lateral side of the cooling housing.

14. The apparatus according to claim 12, wherein the uneven part provided in a region having a larger radius from the center of the cooling housing has a smaller surface area than that of the uneven part in another region having a smaller radius.

15. A method for improving a cooling efficiency of a substrate treatment apparatus, wherein:
the substrate treatment apparatus includes: a support plate that supports the substrate and includes a heater member to heat the substrate; and a cooling unit that forcedly cools the support plate,
wherein the cooling unit includes: a cooling housing to provide a cooling space; a plurality of gas feed nozzles that is disposed in the cooling housing and feeds the cooling gas toward the heater member; and a plurality of gas feed lines that supplies the cooling gas transferred from the outside to the gas feed nozzles, and
wherein the plurality of gas feed lines is directly connected to the gas feed nozzles.

16. The method according to claim 15, wherein the cooling housing has a cylindrical shape with open top, and the gas feed nozzle and the gas feed line are connected through the bottom surface of the cooling housing.

17. The method according to claim 15, wherein a ratio of volume to surface area of the cooling housing is adjusted such that a heat capacity of the cooling housing is being in the range of 100 to 200% relative to a heat capacity of the support plate.

18. The method according to claim 15, wherein a plurality of uneven parts is provided on a lateral side of the cooling housing.

19. The method according to claim 18, wherein a pattern interval and a pattern thickness of the uneven part are adjusted such that the heat capacity of the cooling housing is being in the range of 100 to 200% relative to the heat capacity of the support plate.

20. A substrate treatment apparatus, comprising:
a support plate that supports the substrate and includes a heater member to heat the substrate; and
a cooling unit that forcedly cools the support plate,
wherein the cooling unit includes:
a cooling housing to provide a cooling space;
a plurality of gas feed nozzles that is disposed in the cooling housing and feeds the cooling gas toward the heater member; and
a plurality of gas feed lines that is directly connected to the gas feed nozzles to supply the cooling gas transferred from the outside to the gas feed nozzles;
wherein the gas feed nozzles and the gas feed lines are connected through the bottom surface of the cooling housing, wherein one of the gas feed nozzles is connected to one of the gas feed lines,
a flow rate of the cooling gas supplied from the gas feed lines to the gas feed nozzles is independently controlled,
a ratio of volume to surface area of the cooling housing is adjusted such that a heat capacity of the cooling housing is being in the range of 100 to 200% relative to a heat capacity of the support plate, whereby the heat capacity matches with that of the support plate, and
a plurality of uneven parts is provided on a lateral side of the cooling housing.
